(19) United States
(12) Patent Application Publication
(10) Pub. No.: US 2007/0164763 A1
(43) Pub. Date: Jul. 19, 2007

(54) Method for detecting abnormality of probe card

(75) Inventor: Jung-Kwan Park, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/651,382

(22) Filed: Jan. 9, 2007

(30) Foreign Application Priority Data
Jan. 13, 2006 (KR) 10-2006-0004008

(51) Int. Cl. G01R 31/02

(52) U.S. Cl. 324/758

(57) ABSTRACT

There is provided a system and method for detecting abnormalities in a probe card. A reference image value of a normal contacting pad is set, an image value of a pad is extracted when an error occurs, and the extracted image value is compared to the reference image value. An alarm can be issued when the extracted image value is greater than the reference image value, and the probe card is inspected. The contacting state of the scanning probes and the pads can be automatically checked for abnormalities of the probe card during electrical testing, to accurately determine the contacting status of the scanning probes and the pads, and to not rely on an operator's subjectivity and level of expertise.

### CROSS REFERENCES TO RELATED APPLICATIONS

This U.S. non-provisional patent application claims priority under 35 U.S.C. §119 to Korean Patent Application 10-2006-0004008, filed on Jan. 13, 2006 in the Korean Intellectual Property Office, the entire contents of which are hereby incorporated by reference.

### BACKGROUND OF THE INVENTION

1. Field of the Invention

The present invention relates to systems and methods for detecting abnormalities in a probe card used to measure the characteristics of a semiconductor device, and more particularly, to systems and methods capable of detecting defective contacting of scanning probes of the probe card.

2. Description of the Related Art

Generally, upon completion of the manufacturing process of a semiconductor device, a plurality of chip regions are formed on a wafer, and then are separated into individual semiconductor chips. When the manufacturing process is completed, tests are conducted on the operation of the chips on the wafer, using testing equipment programmed with various test items to test the operation of the semiconductor device.

A plurality of pads for receiving and outputting power and signals are formed on each of the chip regions to operate and test the semiconductor device. Needles (referred to as “scanning probes”) contact the pads to input and output power and signals from and to the chips when conducting tests. The pads of the semiconductor device have an inherent arrangement. The scanning probes contacting the pads are installed on a probe guide, and a probe card made specifically for the type of semiconductor device to be tested is first installed on the testing equipment, and a collective test is then conducted.

The probe card has a plurality of scanning probes installed on a printed circuit board (PCB), and the scanning probes contact the pads on the semiconductor device to conduct electrical tests. The scanning probes of the probe card are arranged to be level to impart force evenly to contact the pads. However, while a test is being conducted, foreign substances can adhere to the ends of the scanning probes, electrical current spikes can destroy the ends of scanning probes, and portions of the scanning probes can be bent so that the probes are non-uniformly arranged.

When abnormal operations of a semiconductor device are detected during its testing, they can be attributed to flaws in the manufacturing process or circuit design of the semiconductor device. But poor contact between the scanning probes of a probe card and the pads cannot be ruled out as a cause for the occurrence of the abnormalities. However, when defects are detected during testing of a semiconductor device, it is normally assumed that the problem lies with the semiconductor device itself, and only afterwards, is the probe card and other testing equipment examined for defects (which consumes much effort and time).

FIG. 1 is a diagram showing scanning probes contacting pads according to the related art.

Referring to FIG. 1, a semiconductor chip has a plurality of pads 10 formed thereon for inputting and outputting signals from and to external devices. The pads 10 are arranged in a variety of configurations according to the type of semiconductor device. When the semiconductor chip is tested, scanning probes 12 installed on a probe card contact the pads 10. The probe card is installed on a probe system that conducts the tests of the semiconductor device, and the probe card moves downward from a position above the semiconductor chip to contact the pads 10 with the scanning probes 12. Here, the scanning probes 12 must contact all the pads 10 that input and output signals with a uniform pressure. Should there be a faulty contact between one or more of the scanning probes 12 and a corresponding one or more of the pads 10 so that they are not properly electrically connected, external signals cannot be properly transmitted to the semiconductor device, resulting in a defective test. Accordingly, the scanning probes 12 installed on the probe card must have their ends aligned uniformly, i.e., to be coplanar, and there must not be any non-conductive materials adhered to the tips of the probes that contact the pads 10. Aside from the above, there are many other possible causes for poor contact between the scanning probes 12 and the pads 10.

FIG. 2 is a diagram showing examples of scanning probes that will cause contacting defects with pads.

Referring to FIG. 2, when viewed from the front, the ends of the scanning probes 12 of the probe card must be aligned evenly. However, the end of scanning probe 12a is bent, the end of scanning probe 12b has been removed by an electrical current spike, and the end of scanning probe 12c has a foreign substance 14 adhered thereto, so that these scanning probes will not contact pads properly.

In the related art, a user had to visually check the contact between the scanning probes 12 and the pads 10. However, because one wafer has tens to hundreds of chips formed thereon, with each chip having several tens of pads, visually inspecting a wafer's pads is difficult. Even if it were possible to visually inspect all the pads on a wafer, the inspection results would differ according to the operator's level of technical expertise and experience, so that cases where faulty contacts are perceived to be sound contacts would remain.

### SUMMARY OF THE INVENTION

In accordance with aspects of the present invention, provided are a system and method for detecting abnormalities in a probe card by detecting poor connections between scanning probes and pads.

In accordance with aspects of the present invention, also provided are a system and method for detecting abnormalities in a probe card when abnormal data is detected during testing of the electrical characteristics of a semiconductor device.

In accordance with one aspect of the present invention, provided is a method for detecting abnormalities in a probe card. The method includes performing a probe test comprising setting a reference image value of a normal contacting pad, extracting an image value of a pad when an error occurs, and comparing the extracted image value to the reference image value. An alarm can be issued when the extracted image value is greater than the reference image value, and the probe card can be inspected.

The method can include repeating the probe test for a plurality of pads in a plurality of chip regions and determining occurrences of data abnormalities on pads at a same location in a plurality of chip regions as an error occurrence point.

The method can include repeating the probe test for a plurality of pads in a plurality of chip regions and determining occurrences of data abnormalities in a same measurement item as an error occurrence point.

The method can include determining the image value of the pad as an average brightness value of the pad.

The extracting of the image value of the pad can include storing an image of the pad as a plurality of pixels, measuring a brightness value of each pixel, and dividing a sum of the brightness value of each pixel by a number of the pixels.

The image of the pad where the error occurs can be stored after the error occurs.

The image of the pad can be stored in a tested chip region after the probe test is conducted, and before moving to a next chip region.

The alarm can be issued when the extracted average brightness value of the pad surpasses the reference image value by more than a tolerance level.

In accordance with another aspect of the invention, provided is a method for performing a probe test, comprising setting a reference image value of a normal contacting pad, extracting an image value of a pad when an error occurs, and comparing the extracted image value to the reference image value.

The method can include repeating the probe test for a plurality of pads in a plurality of chip regions and determining occurrences of data abnormalities on pads at a same location in the plurality of chip regions as an error occurrence point.

The method can include repeating the probe test for a plurality of pads in a plurality of chip regions and determining occurrences of data abnormalities in a same measurement item is determined as an error occurrence point.

The method can include determining the image value of the pad as an average brightness value of the pad.

The extracting of the image value of the pad can comprise storing an image of the pad as a plurality of pixels, measuring a brightness value of each pixel, and dividing a sum of the brightness value of each pixel by a number of the pixels.

The method can include storing the image of the pad when the error occurs.

The method can include storing the image of the pad in a tested chip region after the probe test is conducted, and before moving to a next chip region.

In accordance with another aspect of the invention, provided is an apparatus for detecting abnormalities in a probe card. The apparatus comprises a storage device configured for storing a reference image value of a normal contacting pad, an image extractor configured to extract an image value of a pad when an error occurs, and an image value comparator configured to compare the extracted image value to the reference image value.

The apparatus can further comprises an alarm configured to issue an alarm when an abnormality is detected on the extracted image.

The apparatus can be configured to repeat the probe test for a plurality of pads in a plurality of chip regions and to determine occurrences of data abnormalities on pads at a same location in the plurality of chip regions as an error occurrence point.

The image extractor can be configured to determine the image value of the pad as an average brightness value of the pad.

The image extractor can be configured to store an image of the pad as a plurality of pixels, measure a brightness value of each pixel, and divide a sum of the brightness value of each pixel by a number of the pixels.

### BRIEF DESCRIPTION OF THE DRAWINGS

The accompanying drawings, which are included to provide a further understanding of the invention and are incorporated in and constitute a part of this application, illustrate embodiment(s) of the invention, or aspects thereof. The present invention is not, therefore, limited to the embodiments shown in the accompanying drawings. In the drawings:

FIG. 1 is a diagram showing scanning probes contacting pads according to the related art;

FIG. 2 is a diagram showing examples of defective scanning probes of a probe card according to the related art;

FIG. 3 is a flowchart of an embodiment of a method for detecting abnormalities in a probe card according to aspects of the present invention;

FIG. 4 is a flowchart of an embodiment of a method for extracting image values of a pad according to aspects of the present invention; and

FIGS. 5A through 5C are images showing pads contacted by scanning probes.

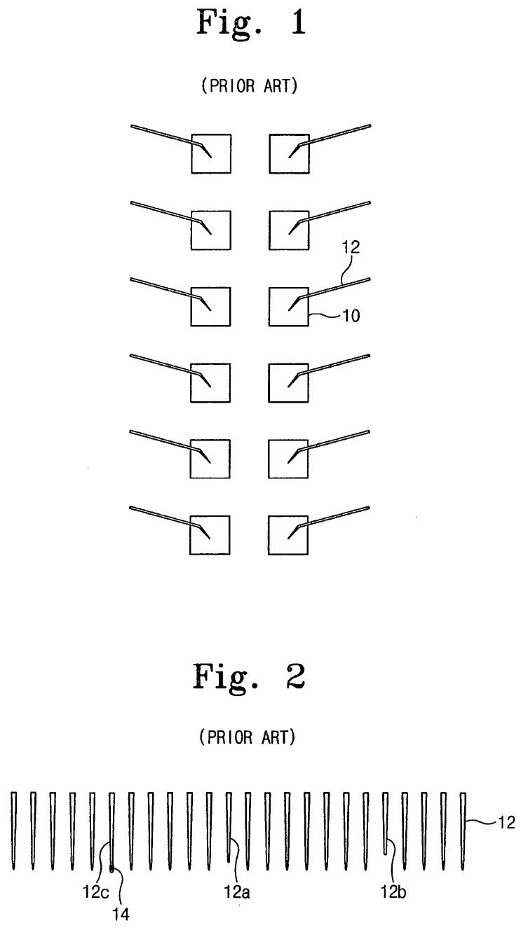

### DETAILED DESCRIPTION OF PREFERRED EMBODIMENTS

Reference will now be made in detail to the accompanying drawings, which depict preferred embodiments, as examples, of aspects of the present invention. However, the present invention is not limited to the embodiments illustrated herein after This invention can be embodied in many different forms and should not be construed as limited to the embodiments set forth herein. Also, like reference numerals in the drawings denote like elements, and thus their overlapping description will be omitted for conciseness.

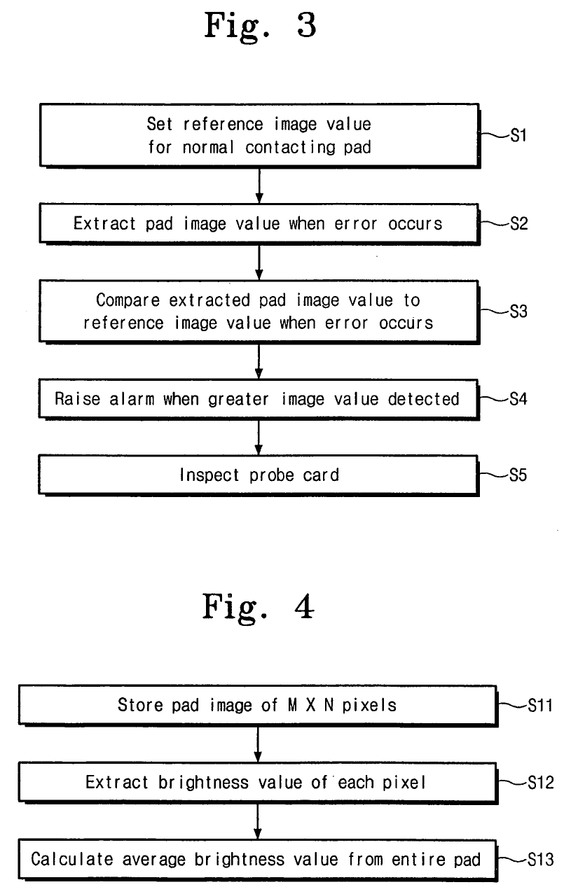

FIG. 3 is a flowchart of an embodiment of a method for detecting abnormalities in a probe card according to aspects of the present invention.

Referring to FIG. 3, a reference value is needed to determine if the scanning probes satisfactorily contact the pads. To determine whether the contact of the scanning probes is satisfactory, brightness values of the pads (on which impressions of the contact with the probes remain) are compared to a brightness value of a pad having normal contact with a probe. First, an image value of a pad with a normal contact is set as a reference value in step S1. The set image value can be an average image value of the pad.

Referring to FIG. 4, the average brightness value of a pad is captured with a pad image of M×N pixels in step S11, the brightness value of each pixel is extracted in step S12, and the extracted brightness values of the pixels are used to calculate an overall average brightness value in step S13. The brightness of the image can be represented in 256 grades of brightness from black to white, where each pixel is stored as an 8 bit gray image. Therefore, each pixel has a value between 0 and 255, and an average value is taken from the sum of all the pixel values.

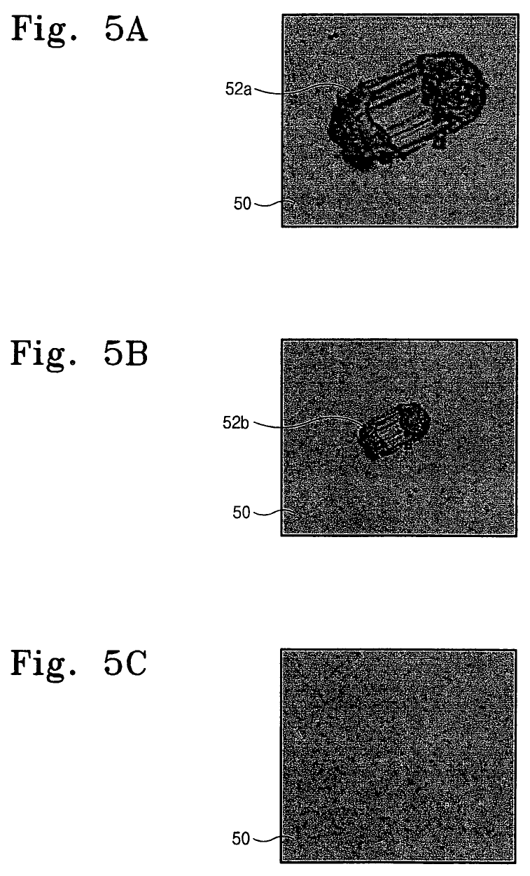

For example, referring to FIG. 5A, when an impression 52a of a scanning probe left on a pad 50 is relatively large, the impression 52a of the scanning probe is darker than other areas of the pad 50, so that the pad's average brightness value is relatively small. Referring to FIG. 5B, the impression 52b of a scanning probe left on a pad 50 is relatively small, so that the pad's average brightness value is greater (i.e., than that of 52a). Referring to FIG. 5C, there is no impression left by a scanning probe on the pad 50 because there was no contact therebetween, so that the pad's brightness value is the largest.

When a reference image value of a pad with normal contact with a probe is set, electrical testing of the chip regions is sequentially performed. The measuring of the semiconductor device's characteristics is performed by sequentially measuring each of the plurality of chip regions formed on the wafer. Here, the electrical test of each chip region is performed using several to several tens of preprogrammed measurement items. Signals are sent through the scanning probes in accordance with each measurement item for the test. During the testing of a semiconductor device or when a contact defect between scanning probes and pads arises prior to the testing, either contact defects continuously arise on pads at the same location on a plurality of chip regions, or data abnormalities are continuously detected in the same measurement item. In these cases, the problem can lie in the circuitry of the semiconductor device or in its manufacture; however, poor contact between the scanning probes and pads being the cause cannot be ruled out either. Therefore, returning to FIG. 3, pads in the same locations where contact defects continuously arise are determined as error occurrence points and the image values for the pads are extracted in step S2. Extracting the image values of the pads can be performed using the method in FIG. 4.

To check for proper contact, the image values of the pads are compared to the reference image value in step S3 of FIG. 3. For example, if the brightness value of a normally contacted pad is 160, and the brightness value of a pad with an error is close to 160, it can be concluded that the contact between the pad and the scanning probe is normal and the problem lies with the semiconductor device itself. However, a pad with a brightness value greater by more than a tolerance level than the brightness value of the normal contacted pad is deemed to have a contact defect with the scanning probe.

When an error occurs and an extracted image value is found to exceed the normal image value by more than a tolerance level, an alarm is raised (or issued) in step S4. The operator disassembles the probe card from the testing equipment and inspects the scanning probes in step S5. If the inspection of the probe card shows foreign substance on the tips of the probes, the probes are cleaned, and if the tips are bent or removed, repairs can be in order.

When the wafer is being electrically measured, a pad image of a chip region can be captured in a chip region in which measuring has been completed, before moving to the next chip region. Here, the images of all the pads of chip regions measured on the wafer are stored, consuming a lot of storage space and storing time. However, the latter is offset by the usefulness of being able to re-examine cases that initially appear to be normal contacts between probes and pads, but are in fact faulty contacts.

Alternately, a method of capturing an image of a pad at the chip region that was being measured at the occurrence of the error and extracting an image value can be used. In this instance, to check the contacting condition of the pad in the previous step, the testing equipment is operated once more. Although this involves changing the position of the equipment, this method is useful in its ability to detect contact defects in a short period of time. Thus, the method of capturing a pad image of a chip region can be varied according to need.

The above-described method preferably involves pre-programming a measuring system, automatically operating testing equipment when recurring abnormalities are detected in the same pad or the same measured item, and determining whether the contacting of a scanning probe is normal or not. When it is determined that the contacting of the scanning probe is not defective, electrical tests can be continuously conducted.

The reference image value of a normal contacting pad can be set in a number of different ways. For example, the reference image value of a normal contacting pad can be set from an initially measured chip region of each wafer, from an initially measured chip region of an initially measured wafer of each lot, or as an arbitrarily set value that is periodically reset. On the other hand, the setting of a reference image value of a normal contacting pad can be done by taking measurements from a plurality of positions on the wafer and setting reference values by region on the wafer, and not set based on measurements taken from an initially measured chip region. A wafer that has completed its manufacturing process can be non-uniform in lightness and darkness. Taking this into account, image values can be set by region. When an error occurs, the reference image value from the location in which the chip region is formed is selected, and the probe card can be checked for abnormalities.

Those skilled in the art will appreciated that the methods of FIGS. 3 and 4 can be carried out by one or more computer controlled systems, subsystems, and/or devices having or coupled to imaging sensors or devices with appropriate resolution for acquiring images sufficient to determine brightness differences at a pad level. Such imaging sensors or devices are presently available, so not described herein in detail. The functionality of the methods can be implemented in software, hardware, firmware of some combination thereof, in cooperation with available computer controlled systems, subsystems, and/or devices. In the preferred form, the functionality of FIGS. 3 and 4 can be implemented as an augmentation or modification to systems typically used for semiconductor ship testing.

As described above, the present invention automatically checks the contacting state of the scanning probes and the pads to check abnormalities of a probe card during electrical testing, to accurately determine the contacting status of the scanning probes and the pads and not to rely on an operator's subjectivity and level of expertise.

Also, when continued errors occur at the same pad or the same measurement item, before the semiconductor device is treated as defective, abnormalities in the probe card can be detected, so that wafer yield can be increased and unnecessary time and effort expended to locate circuit or manufacturing defects can be reduced.

It will be apparent to those skilled in the art that various modifications and variations can be made in the present invention. Thus, it is intended that the present invention covers the modifications and variations of this invention. It is, therefore, intended by the following claims to claim that which is literally described and all equivalents thereto, including all modifications and variations that fall within the scope of each claim.

What is claimed is:

1. A method for detecting abnormalities in a probe card, the method includes performing a probe test comprising:
setting a reference image value of a normal contacting pad;
extracting an image value of a pad when an error occurs;
comparing the extracted image value to the reference image value;
issuing an alarm when an abnormality is detected on the extracted image; and
inspecting the probe card.

2. The method of claim 1, further comprising repeating the probe test for a plurality of pads in a plurality of chip regions and determining occurrences of data abnormalities on pads at a same location in the plurality of chip regions as an error occurrence point.

3. The method of claim 1, further comprising repeating the probe test for a plurality of pads in a plurality of chip regions and determining occurrences of data abnormalities in a same measurement item as an error occurrence point.

4. The method of claim 1, further comprising determining the image value of the pad as an average brightness value of the pad.

5. The method of claim 4, wherein the extracting of the image value of the pad comprises:
storing an image of the pad as a plurality of pixels;
measuring a brightness value of each pixel; and
dividing a sum of the brightness value of each pixel by a number of the pixels.

6. The method of claim 5, further comprising storing the image of the pad when the error occurs.

7. The method of claim 5, further comprising storing the image of the pad in a tested chip region after the probe test is conducted, and before moving to a next chip region.

8. The method of claim 4, wherein the alarm is issued when the extracted average brightness value of the pad surpasses the reference image value by more than a tolerance level.

9. A method for performing a probe test, comprising:
setting a reference image value of a normal contacting pad;
extracting an image value of a pad when an error occurs; and
comparing the extracted image value to the reference image value.

10. The method of claim 9, further comprising repeating the probe test for a plurality of pads in a plurality of chip regions and determining occurrences of data abnormalities on pads at a same location in the plurality of chip regions as an error occurrence point.

11. The method of claim 9, further comprising repeating the probe test for a plurality of pads in a plurality of chip regions and determining occurrences of data abnormalities in a same measurement item is determined as an error occurrence point.

12. The method of claim 9, further comprising determining the image value of the pad as an average brightness value of the pad.

13. The method of claim 12, wherein the extracting of the image value of the pad comprises:
storing an image of the pad as a plurality of pixels;
measuring a brightness value of each pixel; and
dividing a sum of the brightness value of each pixel by a number of the pixels.

14. The method of claim 13, further comprising storing the image of the pad when the error occurs.

15. The method of claim 13, further comprising storing the image of the pad in a tested chip region after the probe test is conducted, and before moving to a next chip region.

16. An apparatus for detecting abnormalities in a probe card, the apparatus comprising:
a storage device configured for storing a reference image value of a normal contacting pad;
an image extractor configured to extract an image value of a pad when an error occurs; and
an image value comparator configured to compare the extracted image value to the reference image value.

17. The apparatus of claim 16, further comprising:
an alarm configured to issue an alarm when an abnormality is detected on the extracted image.

18. The apparatus of claim 16, wherein the apparatus is configured to repeat the probe test for a plurality of pads in a plurality of chip regions and to determine occurrences of data abnormalities on pads at a same location in the plurality of chip regions as an error occurrence point.

19. The apparatus of claim 16, wherein the image extractor is configured to determine the image value of the pad as an average brightness value of the pad.

20. The apparatus of claim 19, wherein the image extractor is configured to:
store an image of the pad as a plurality of pixels;
measure a brightness value of each pixel; and
divide a sum of the brightness value of each pixel by a number of the pixels.
